(19) United States
(12) Patent Application Publication
(10) Pub. No.: US 2021/0249845 A1
(43) Pub. Date: Aug. 12, 2021

(54) GERMANIUM-BASED LASER DIODE

(71) Applicant: INTERNATIONAL BUSINESS MACHINES CORPORATION, Armonk, NY (US)

(72) Inventors: Zuoguang Liu, Schenectady, NY (US); Kangguo Cheng, Schenectady, NY (US)

(21) Appl. No.: 16/788,385

(22) Filed: Feb. 12, 2020

(51) Int. Cl. H01S 5/30; H01S 5/22; H01S 5/32

(52) U.S. Cl. CPC H01S 5/3086; H01L 33/0008; H01S 5/32; H01S 5/2226

(57) ABSTRACT

A method is presented for forming a germanium (Ge) laser diode with direct bandgap for laser generation. The method includes forming an intrinsic Ge active layer over a substrate, forming a p+ region and an n+ region adjacent the intrinsic Ge active layer, such that the p+ region, the n+ region, and the intrinsic Ge active layer collectively define a p-i-n diode, and forming metal contacts to the p+ and n+ regions.

### BACKGROUND

The present invention relates generally to semiconductor devices, and more specifically, to a germanium laser diode with direct bandgap for laser generation.

There has been considerable effort to integrate germanium (Ge) with silicon (Si). Ge has a smaller bandgap and with tensile-strained heteroepitaxial growth, with an optical absorption band edge up to 1600 nm wavelength. With strain up to 1.7%, Ge can also provide a direct bandgap material, suitable for light emission. Heteroepitaxial growth techniques including, but not limited to, chemical vapor deposition (CVD), have been developed to grow high-quality crystalline germanium and to reduce a number of crystal defects introduced by a lattice constant mismatch between Si and Ge.

### SUMMARY

In accordance with an embodiment, a method is provided for forming a germanium (Ge) laser diode with direct bandgap for laser generation. The method includes forming an intrinsic Ge active layer over a substrate, forming a p+ region and an n+ region adjacent the intrinsic Ge active layer, wherein the p+ region, the n+ region, and the intrinsic Ge active layer collectively define a p-i-n diode, and forming metal contacts to the p+ and n+ regions.

In accordance with another embodiment, a method is provided for forming a germanium (Ge) laser diode with direct bandgap for laser generation. The method includes forming a stack including alternating intrinsic Ge active layers over a substrate, forming a p+ region and an n+ region adjacent the stack including the alternating intrinsic Ge active layers, wherein the p+ region, the n+ region, and the alternating intrinsic Ge active layers collectively define a p-i-n diode, and forming metal contacts to the p+ and n+ regions.

In accordance with yet another embodiment, a method is provided for forming a germanium (Ge) laser diode with enhanced tensile strain. The method includes epitaxially growing a graded silicon germanium (SiGe) strain relaxation buffer (SRB) over a substrate, epitaxially growing first and second sacrificial layers over the graded SiGe SRB, forming an n-type doped semiconductor layer over the first and second sacrificial layers, forming an n-type doped Ge layer over the n-type doped semiconductor layer, forming a p-type doped semiconductor layer over the n-type doped Ge layer, wherein the n-type doped semiconductor layer, the n-type doped Ge layer, and the p-type doped semiconductor layer collectively define a diode, and depositing a first stress film over the p-type doped semiconductor layer, wherein the first stress film subsequently transfers tensile strain to the n-type doped Ge layer.

In accordance with an embodiment, a Ge laser diode is provided with direct bandgap for laser generation. The Ge laser diode includes a stack including alternating intrinsic Ge active layers disposed over a substrate, a p+ region and an n+ region disposed adjacent the stack including the alternating intrinsic Ge active layers, wherein the p+ region, the n+ region, and the alternating intrinsic Ge active layers collectively define a diode, and metal contacts directly contacting the p+ and n+ regions.

In accordance with another embodiment, a Ge laser diode is provided with enhanced tensile strain. The Ge laser diode includes a stack disposed over a substrate, wherein the stack includes an n-type doped Ge layer, sandwiched by a p-type doped semiconductor layer and an n-type doped semiconductor layer, a first stress film and a second stress film abutting the p-type doped semiconductor layer and the n-type doped semiconductor layer, wherein the first stress film and the second stress film transfer tensile strain to the n-type doped Ge layer.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE DRAWINGS

The invention will provide details in the following description of preferred embodiments with reference to the following figures wherein:

FIG. 1 is a cross-sectional view of a semiconductor structure where an intrinsic germanium (Ge) active layer is formed over a substrate, in accordance with an embodiment of the present invention;

FIG. 2 is a cross-sectional view of the semiconductor structure of FIG. 1 where the p+ region is patterned for the p-i-n laser diode, in accordance with an embodiment of the present invention;

FIG. 3 is a cross-sectional view of the semiconductor structure of FIG. 2 where the p+ region is formed either by dopant implantation or epitaxial growth, in accordance with an embodiment of the present invention;

FIG. 4 is a cross-sectional view of the semiconductor structure of FIG. 3 where the n+ region is patterned and an n+ region is formed either by dopant implantation or epitaxial growth, in accordance with an embodiment of the present invention;

FIG. 5 is a cross-sectional view of the semiconductor structure of FIG. 4 where metal contacts are formed to the p+ and n+ regions, in accordance with an embodiment of the present invention;

FIG. 6 is a cross-sectional view of a semiconductor structure where the positions of the p+ region or n+ region are horizontally misaligned, in accordance with another embodiment of the present invention;

FIG. 7 is a cross-sectional view of a semiconductor structure where a stack of intrinsic Ge active layers is formed over a substrate, in accordance with another embodiment of the present invention;

FIG. 8 is a cross-sectional view of the semiconductor structure of FIG. 7 where the p+ region is patterned, in accordance with an embodiment of the present invention;

FIG. 9 is a cross-sectional view of the semiconductor structure of FIG. 8 where the p+ region is epitaxially grown, in accordance with an embodiment of the present invention;

FIG. 10 is a cross-sectional view of the semiconductor structure of FIG. 9 where the n+ region is patterned, in accordance with an embodiment of the present invention;

FIG. 11 is a cross-sectional view of the semiconductor structure of FIG. 10 where the n+ region is epitaxially grown, in accordance with an embodiment of the present invention;

FIG. 12 is a cross-sectional view of the semiconductor structure of FIG. 11 where an inter-layer dielectric (ILD) is deposited, in accordance with an embodiment of the present invention;

FIG. 13 is a cross-sectional view of the semiconductor structure of FIG. 12 where the dummy gate is removed to expose the stack of intrinsic Ge active layers, in accordance with an embodiment of the present invention;

FIG. 14 is a cross-sectional view of the semiconductor structure of FIG. 13 where the sacrificial layers of the stack of intrinsic Ge active layers are selectively removed, in accordance with an embodiment of the present invention;

FIG. 15 is a cross-sectional view of the semiconductor structure of FIG. 14 where the gaps defined by the removal of the sacrificial layers are filled with a dielectric, in accordance with an embodiment of the present invention;

FIG. 16 is a cross-sectional view of the semiconductor structure of FIG. 15 where further ILD is deposited and metal contacts are formed to the p+ and n+ regions, in accordance with an embodiment of the present invention;

FIG. 17 is a cross-sectional view of a semiconductor structure where a stress film is deposited over a stack of semiconductor layers formed over a substrate, a portion of the stack patterned, in accordance with another embodiment of the present invention;

FIG. 18 is a cross-sectional view of the semiconductor structure of FIG. 17 where spacers are formed adjacent the patterned stack, in accordance with an embodiment of the present invention;

FIG. 19 is a cross-sectional view of the semiconductor structure of FIG. 18 where a directional etch takes place to expose a top surface of a sacrificial silicon (Si) layer, in accordance with an embodiment of the present invention;

FIG. 20 is a cross-sectional view of the semiconductor structure of FIG. 19 where a sacrificial silicon germanium (SiGe) layer is undercut and a stress film is deposited in the undercut portion, in accordance with an embodiment of the present invention;

FIG. 21 is a cross-sectional view of the semiconductor structure of FIG. 20 where the sacrificial Si layer is selectively etched to create an undercut between the stress film and a graded SiGe strain relaxation buffer (SRB) layer, in accordance with an embodiment of the present invention;

FIG. 22 is a cross-sectional view of the semiconductor structure of FIG. 21 where the stress film is relaxed (or expanded) to produce tensile strain in the laser diode, in accordance with an embodiment of the present invention;

FIG. 23 is a cross-sectional view of the semiconductor structure of FIG. 22 where a further ILD is deposited and metal contacts are formed, in accordance with an embodiment of the present invention; and

FIG. 24 is a cross-sectional view of the semiconductor structure where a continuous layer of stress film is formed under the patterned stack of semiconductor layers, in accordance with another embodiment of the present invention.

Throughout the drawings, same or similar reference numerals represent the same or similar elements.

### DETAILED DESCRIPTION

Embodiments in accordance with the present invention provide methods and devices for forming a germanium (Ge) laser diode with direct bandgap for laser generation. A Ge laser can obtain laser light at approximately 1550 nm (NIR) from the direct band gap of Ge. Ge is attractive due to its unique NIR wavelength and also due to its compatibility with Si semiconductor technology. However, bulk Ge is an indirect bandgap (Eg) material, thus not suitable for laser application. The direct Eg 0.8 eV is only 0.136 eV greater than the indirect Eg 0.66 eV. By applying tensile strain on n-type Ge, the difference between direct Eg and indirect Eg can be narrowed to enable Ge for laser applications. Nevertheless, when epitaxial Ge grows on Si, compressive strain instead of tensile strain is produced in Ge.

Embodiments in accordance with the present invention alleviate such compressive strain issues by providing methods and devices for employing a Ge laser structure including a single thin Ge layer along <100> of less than 5 nm thickness (preferentially 3 nm or less) on oxide or nitride that serves as the intrinsic Ge active layer in the p-i-n laser diode. The device structure of the exemplary embodiments of the present invention further includes another Ge laser structure including a stack of alternating layers of thin Ge layers along <100> of less than 5 nm thickness (preferentially 3 nm or less) on oxide or nitride that serves as the intrinsic Ge active layer in the p-i-n laser diode. The device structure of the exemplary embodiments of the present invention further includes yet another Ge laser structure including epitaxially growing a strain relaxation buffer (SRB) layer (e.g., graded SiGe) on top of a Si substrate, epitaxially growing a stack of sacrificial layer and Ge on the SRB layer, and forming stress films at both the top and bottom of the Ge laser layers to produce tensile strain in the Ge layer. The tensily strained Ge laser includes stressors (or stress films) on top and underneath of the diode laser. In one example, the sacrificial Si and sacrificial SiGe pillars underneath the diode are relied on for anchoring during the fabrication. In another example, an external anchor can be provided at the ends of the stack, where the entire sacrificial Si and SiGe can be removed and back-filled with stress nitride.

Examples of semiconductor materials that can be used in forming such structures include silicon (Si), germanium (Ge), silicon germanium alloys (SiGe), silicon carbide (SiC), silicon germanium carbide (SiGeC), III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

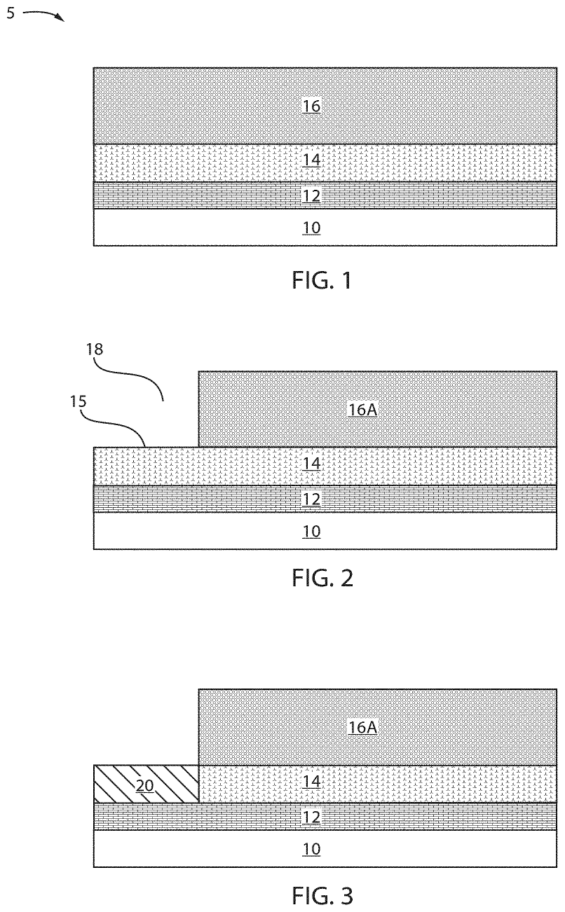

FIG. 1 is a cross-sectional view of a semiconductor structure where an intrinsic germanium (Ge) active layer is formed over a substrate, in accordance with an embodiment of the present invention.

A semiconductor structure 5 includes a semiconductor substrate 10. A dielectric layer 12 is formed over the semiconductor substrate 10. An intrinsic germanium (Ge) active layer 14 is formed over the dielectric layer 12. A dielectric cap layer 16 is then formed over the intrinsic Ge active layer 14.

The substrate 10 can be crystalline, semi-crystalline, microcrystalline, or amorphous. The substrate 10 can be essentially (e.g., except for contaminants) a single element (e.g., silicon), primarily (e.g., with doping) of a single element, for example, silicon (Si) or germanium (Ge), or the substrate 10 can include a compound, for example, GaAs, SiC, or SiGe. The substrate 10 can also have multiple material layers. In some embodiments, the substrate 10 includes a semiconductor material including, but not necessarily limited to, silicon (Si), silicon germanium (SiGe), silicon carbide (SiC), Si:C (carbon doped silicon), silicon germanium carbide (SiGeC), carbon doped silicon germanium (SiGe:C), III-V (e.g., GaAs, AlGaAs, InAs, InP, etc.), II-V compound semiconductor (e.g., ZnSe, ZnTe, ZnCdSe, etc.) or other like semiconductor. In addition, multiple layers of the semiconductor materials can be used as the semiconductor material of the substrate 10. In some embodiments, the substrate 10 includes both semiconductor materials and dielectric materials. The semiconductor substrate 10 can also include an organic semiconductor or a layered semiconductor such as, for example, Si/SiGe, a silicon-on-insulator or a SiGe-on-insulator.

The dielectric layer 12 can include, but is not limited to, SiN, SiOCN, SiOC, SiBCN, SO₂, or ultra-low-k (ULK) materials, such as, for example, porous silicates, carbon doped oxides, silicon dioxides, silicon nitrides, silicon oxynitrides, carbon-doped silicon oxide (SiCOH) and porous variants thereof, silsesquioxanes, siloxanes, or other dielectric materials having, for example, a dielectric constant in the range of about 2 to about 10.

In some embodiments, the dielectric layer 12 can be conformally deposited using atomic layer deposition (ALD) or, chemical vapor deposition (CVD). Variations of CVD processes suitable for forming the dielectric layer 12 include, but are not limited to, Atmospheric Pressure CVD (APCVD), Low Pressure CVD (LPCVD) and Plasma Enhanced CVD (PECVD), Metal-Organic CVD (MOCVD) and combinations thereof can also be employed.

The intrinsic Ge active layer 14 can have a thickness of less than 5 nm. In one example, the thickness of the intrinsic Ge active layer 14 is approximately 3 nm or less. The intrinsic Ge active layer 14 can be deposited by wafer bonding or HEtero-Layer-Lift-Off (HELLO) for ultra-thin-body (UTB) germanium-on-insulator (GeOI) substrates. HELLO is a Ge layer transfer technology utilizing a SiGe etch stop layer in the donor structure to precisely control GeOI body thickness (T_{body}). HELLO technology is effective in mitigating thickness fluctuation issues in UTB GeOI during the Ge thinning process.

The dielectric cap layer 16 can include a dielectric material such as silicon dioxide, silicon nitride, or silicon oxynitride. The dielectric cap layer 16 can be formed utilizing a conventional deposition process such as, for example, CVD or PECVD. Alternatively, the dielectric cap layer 16 can be formed by a thermal process such as, for example, oxidation or nitridation. Any combination of the above mentioned processes can also be used in forming the dielectric cap layer 16.

FIG. 2 is a cross-sectional view of the semiconductor structure of FIG. 1 where the p+ region is patterned for the p-i-n laser diode, in accordance with an embodiment of the present invention.

In various example embodiments, the dielectric cap layer 16 is patterned to create opening 18. The patterning results in remaining dielectric cap layer 16A and exposes the top surface 15 of the intrinsic Ge active layer 14. The region opened can be either the p+ region or the n+ region. In the instant case, in a non-limiting manner, the p+ region will first be created.

FIG. 3 is a cross-sectional view of the semiconductor structure of FIG. 2 where the p+ region is formed either by dopant implantation or epitaxial growth, in accordance with an embodiment of the present invention.

In various example embodiments, the p+ region 20 is created adjacent the remaining intrinsic Ge active layer 14. The p+ region 20 can be created by dopant implantation. For example, boron (B), gallium (Ga) or indium (In), which are p-type dopants, are implanted and annealed to activate the p+ region 20. In another example, Ge at the p+ region can be etched away and B or Ga-doped SiGe (or Ge, Si) can be epitaxially grown to form the p+ region 20.

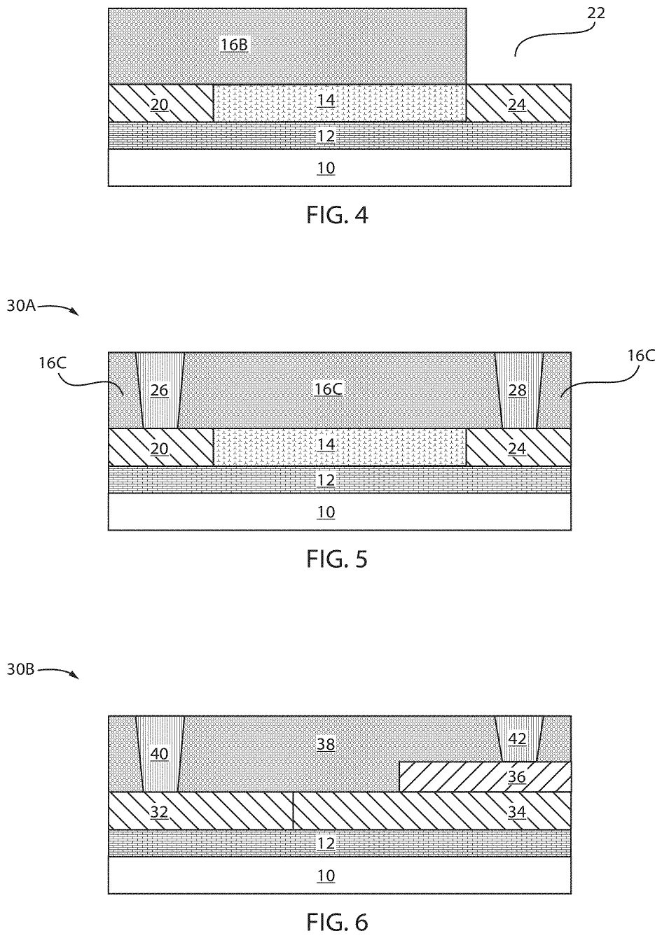

FIG. 4 is a cross-sectional view of the semiconductor structure of FIG. 3 where the n+ region is patterned and an n+ region is formed either by dopant implantation or epitaxial growth, in accordance with an embodiment of the present invention.

In various example embodiments, the remaining dielectric cap layer 16A is patterned and an n+ region 24 is created in an opening 22 adjacent the intrinsic Ge active layer 14. The intrinsic Ge active layer 14 is collinear with the p+ region 20 and the n+ region 24. Stated differently, the intrinsic Ge active layer 14 is horizontally aligned with the p+ region 20 and the n+ region 24. The n+ region 24 can be created by dopant implantation. For example, phosphorous (P), arsenic (As) or antimony (Sb), which are n-type dopants, are implanted and annealed to activate the n+ region 24. In another example, Ge at the n+ region can be etched away and P-doped Si (or SiGe, Ge) can be epitaxially grown to form the n+ region 24. The patterned dielectric cap layer can be designated as 16B. The p+ region 20, the n+ region 24, and the intrinsic Ge active layer 14 collectively define a p-i-n diode.

Non-limiting doping concentration ranges for the p+ region 20 or the n+ region 24 can be, e.g., 1×10¹⁹/cm³ to 1×10²¹ cm³ (wide range) or 5×10¹⁹/cm³ to 5×10²⁰ cm³ (narrow range).

FIG. 5 is a cross-sectional view of the semiconductor structure of FIG. 4 where metal contacts are formed to the p+ and n+ regions, in accordance with an embodiment of the present invention.

In various example embodiments, metal contacts 26, 28 are formed to the p+ and n+ regions 20, 24, respectively. The remaining dielectric cap layer can be designated as 16C.

Thus, in laser structure 30A, a thin Ge layer along <100> of less than 5 nm thickness (preferentially 3 nm or less) on oxide or nitride serves as the intrinsic Ge active layer in the p-i-n laser diode. A p+ region 20 and an n+ region 24 can be formed with Si, SiGe, or Ge. The laser structure 30A can potentially have efficient light emission at approximately 1550 nm from the direct band gap of Ge. Laser structure 30A can also be referred to as a p-i-n Ge-based laser diode.

FIG. 6 is a cross-sectional view of a semiconductor structure where the positions of the p+ region or n+ region are horizontally misaligned, in accordance with another embodiment of the present invention.

In another example embodiment, the p+ region and the n+ region on the p-i-n Ge-based laser diode can be formed with different positioning with respect to the laser structure 30A. In particular, the p+ region 32 can be formed adjacent the intrinsic Ge active layer 34, whereas the n+ region 36 can be formed over the intrinsic Ge active layer 34. Similarly to laser structure 30A, in laser structure 30B, an oxide or nitride cap 38 is deposited and metal contacts 40, 42 are formed to the p+ region 32 and the n+ region 36, respectively. Therefore, in laser structure 30B, the p+ region 32 is horizontally offset from the n+ region 36. The p+ region 32, the n+ region 36, and the intrinsic Ge active layer 34 collectively define a p-i-n diode. Laser structure 30B can also be referred to as a p-i-n Ge-based laser diode.

Regarding FIGS. 5 and 6, although not shown, the exemplary embodiments can further include mirrors, such as Bragg reflectors, below and above the lasing layers.

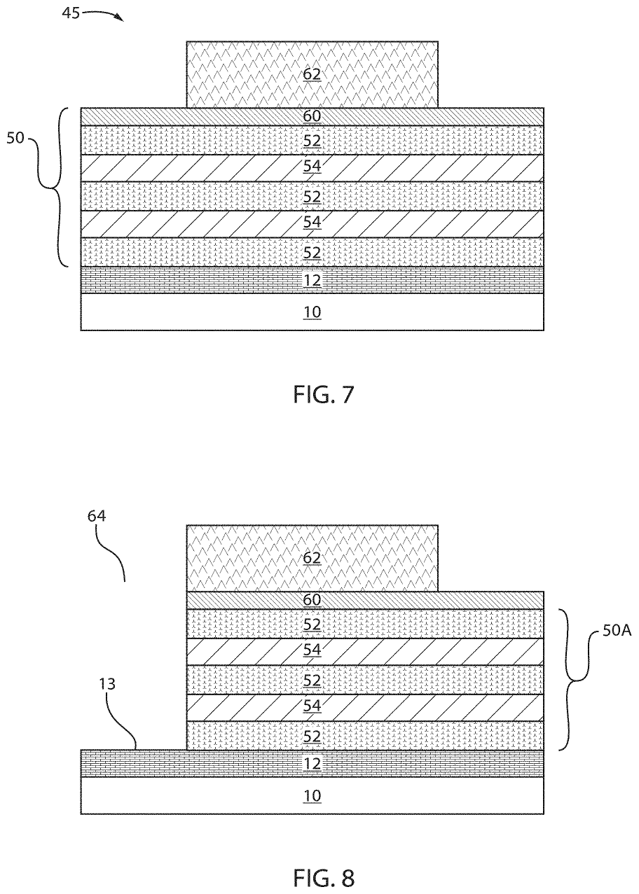

FIG. 7 is a cross-sectional view of a semiconductor structure where a stack of intrinsic Ge active layers is formed over a substrate, in accordance with another embodiment of the present invention.

In another example embodiment, instead of employing a single Ge active layer, a stack including a plurality of Ge active layers is used. Similarly to FIG. 1, a dielectric layer 12 is formed over a substrate 10 in structure 45. A stack 50 is formed over the dielectric layer 12. The stack 50 includes alternating layers of intrinsic Ge active layers 52 and semiconductor layers 54. Stated differently, dielectric layers separate the alternating intrinsic Ge active 52 layers within the stack 50. Semiconductor layers 54 can be, e.g., silicon (Si) layers. The intrinsic Ge active layers 52 can each have a thickness of less than 5 nm. In one example, the thickness of each of the intrinsic Ge active layers 52 is approximately 3 nm or less. The intrinsic Ge active layers 52 can be epitaxially grown. In the instant example, three intrinsic Ge active layers 52 are illustrated. However, one skilled in the art can contemplate using any number of intrinsic Ge active layers 52 to form the stack 50.

A dielectric cap layer 60 is then formed over the stack 50 including alternating layers of intrinsic Ge active layers 52. A dummy gate 62 is also formed over the dielectric cap layer 60 for the active laser region.

Dummy gate 62 materials include, but are not limited to, a thin layer of dummy oxide SiO₂ followed by any one or more of amorphous or polycrystalline Si, SiO₂, SiON, SiGe, Ge, GeO₂, amorphous C, BC, CN, etc.

FIG. 8 is a cross-sectional view of the semiconductor structure of FIG. 7 where the p+ region is patterned, in accordance with an embodiment of the present invention.

In various example embodiments, the dielectric cap layer 60 is patterned to create opening 64. The patterning results in exposing the top surface 13 of the dielectric layer 12. The patterning also results in stack 50A remaining over the substrate 10. The region opened can be either the p+ region or the n+ region. In the instant case, in a non-limiting manner, the p+ region will first be created.

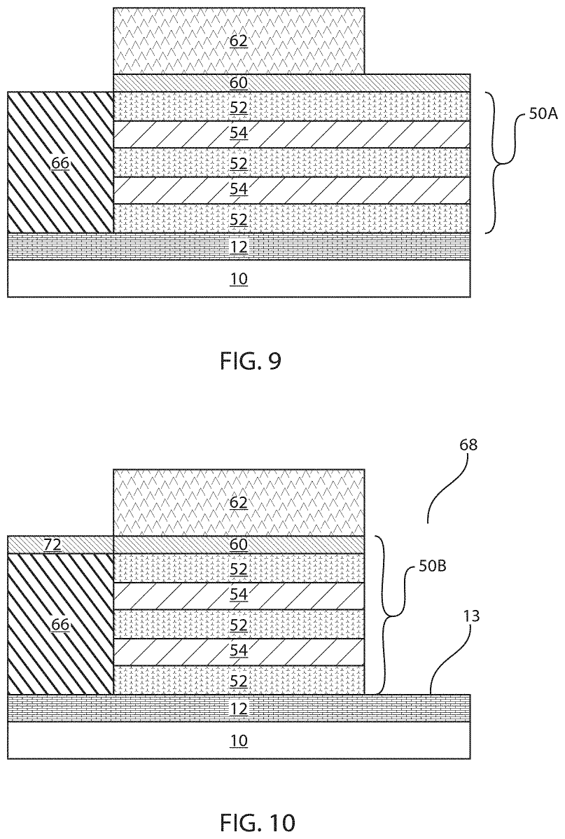

FIG. 9 is a cross-sectional view of the semiconductor structure of FIG. 8 where the p+ region is epitaxially grown, in accordance with an embodiment of the present invention.

In various example embodiments, the p+ region 66 is created adjacent the remaining stack 50A. In one example, Ge of the stack 50 at the p+ region can be etched away and B or Ga-doped Ge (or SiGe, Si) can be epitaxially grown to form the p+ region 66.

FIG. 10 is a cross-sectional view of the semiconductor structure of FIG. 9 where the n+ region is patterned, in accordance with an embodiment of the present invention.

In various example embodiments, a dielectric cap 72 is formed over the p+ region 66 and the remaining dielectric cap layer 60 is patterned to create opening 68. The patterning results in exposing the top surface 13 of the dielectric layer 12. The patterning also results in stack 50B remaining over the substrate 10.

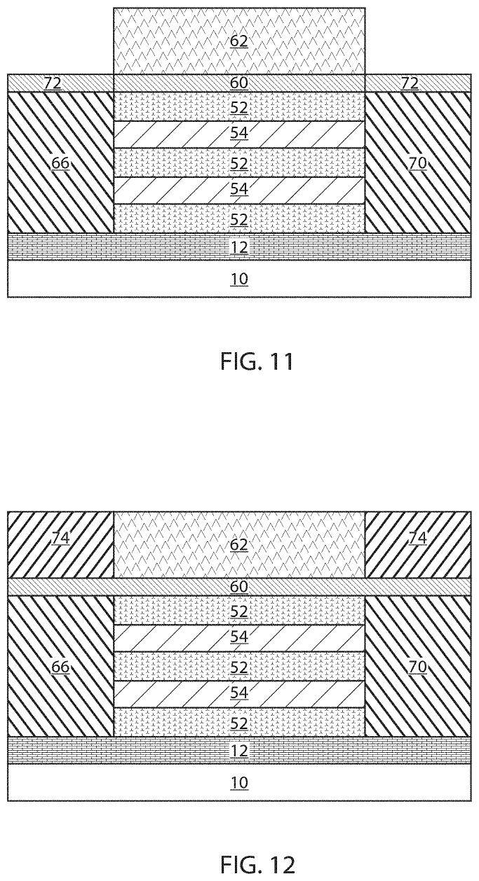

FIG. 11 is a cross-sectional view of the semiconductor structure of FIG. 10 where the n+ region is epitaxially grown, in accordance with an embodiment of the present invention.

In various example embodiments, an n+ region 70 is created adjacent the remaining stack 50B. In one example, Ge of the remaining stack 50B at the n+ region can be etched away and p-doped Si (or SiGe, Ge) can be epitaxially grown to form the n+ region 70. A dielectric cap 72 is formed over the n+ region 70.

The p+ region 66 and the n+ region 70 extend a length of the remaining stack 50B. The p+ region 66 and the n+ region 70 directly contact sidewalls of the remaining stack 50B.

FIG. 12 is a cross-sectional view of the semiconductor structure of FIG. 11 where an inter-layer dielectric (ILD) is deposited, in accordance with an embodiment of the present invention.

In various example embodiments, an inter-layer dielectric (ILD) 74 is deposited and planarized by, e.g., chemical-mechanical planarization (CMP).

The ILD 74 can be any suitable dielectric such as, for example, silicon oxide (SiO), silicon nitride (SiN), silicon oxynitride, silicon boron carbon nitride (SiBCN), silicon oxygen carbon nitride (SiOCN), silicon oxygen carbon (SiOC), silicon carbon nitride (SiCN), hydrogenated oxidized silicon carbon (SiCOH), or any suitable combination of those materials. In one example, the ILD 74 can be a low-k oxide.

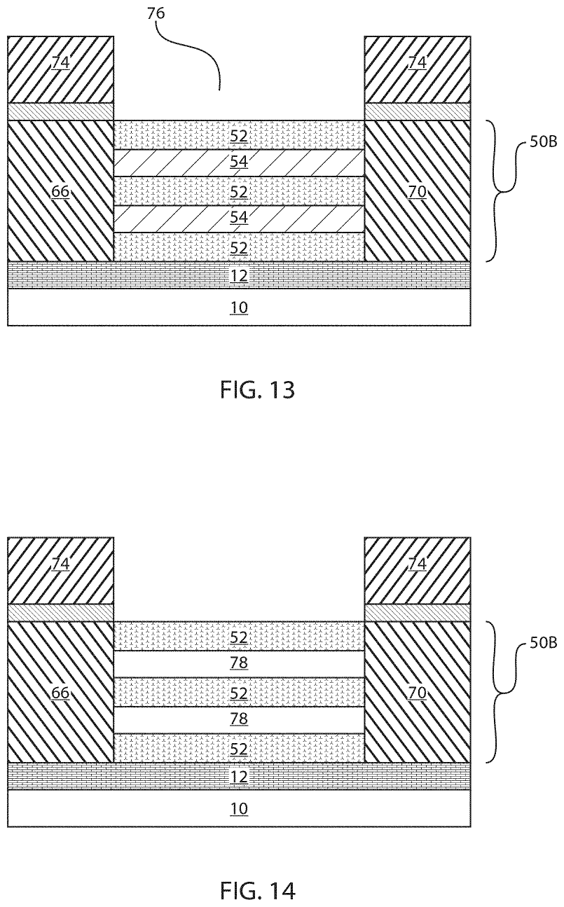

FIG. 13 is a cross-sectional view of the semiconductor structure of FIG. 12 where the dummy gate is removed to expose the stack of intrinsic Ge active layers, in accordance with an embodiment of the present invention.

In various example embodiments, the dummy gate 62 is removed, which results in opening 76 over the remaining stack 50B. Additionally, the dielectric cap 72 is removed to expose a top surface of the remaining stack 50B.

The dummy gate 62 can be removed by implementing a reactive ion etch (RIE) process and/or a wet etching process. If the dummy gate 62 is made of amorphous or poly-Si, it can be etched in hot NH₄OH or Tetramethylammonium hydroxide (TMAH) chemistries in a manner that is selective to the ILD 74 and the materials of remaining stack 50B.

FIG. 14 is a cross-sectional view of the semiconductor structure of FIG. 13 where the sacrificial layers of the stack of intrinsic Ge active layers are selectively removed, in accordance with an embodiment of the present invention.

In various example embodiments, the sacrificial layers 54 of the remaining stack 50B of intrinsic Ge active layers 52 are selectively removed. The removal results in gaps or openings 78 formed adjacent or between the intrinsic Ge active layers 52.

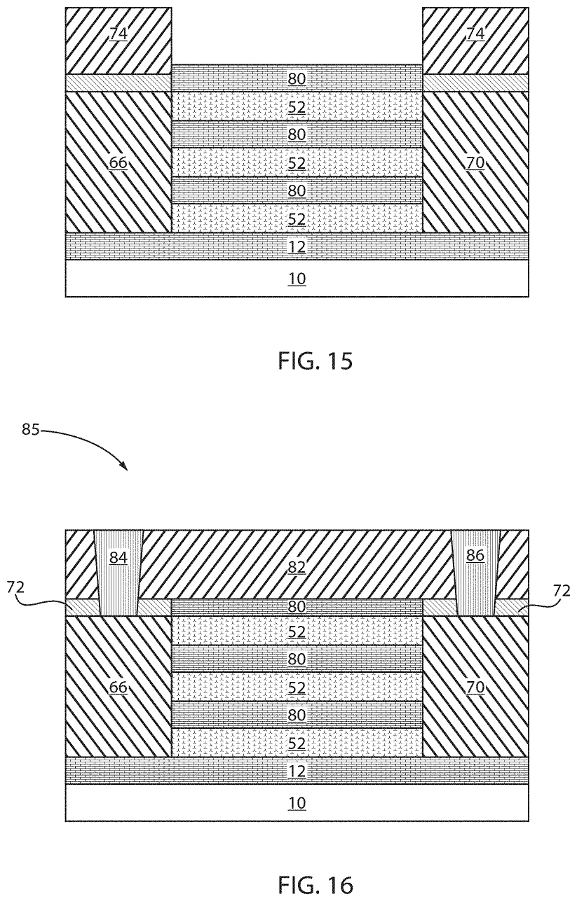

FIG. 15 is a cross-sectional view of the semiconductor structure of FIG. 14 where the gaps defined by the removal of the sacrificial layers are filled with a dielectric, in accordance with an embodiment of the present invention.

In various example embodiments, a dielectric material is deposited to form dielectric material layers 80 that fill the gaps or openings 78. Additionally, a dielectric material layer 80 is also formed over the top of the remaining stack 50B. Thus, in the instant example, there are three intrinsic Ge active layers 52 and three dielectric material layers 80. The dielectric material layers 80 can include, e.g., SiO₂. The dielectric material layers 80 can be deposited by, e.g., ALD.

FIG. 16 is a cross-sectional view of the semiconductor structure of FIG. 15 where further ILD is deposited and metal contacts are formed to the p+ and n+ regions, in accordance with an embodiment of the present invention.

In various example embodiments, further ILD 82 is deposited and metal contacts 84, 86 are formed to the p+ and n+ regions 66, 70, respectively, to create laser diode structure 85.

The metal contacts 84, 86 can be of any suitable conducting material, such as, for example, a metal (e.g., tungsten, titanium, tantalum, ruthenium, zirconium, cobalt, copper, aluminum, lead, platinum, tin, silver, gold), a conducting metallic compound material (e.g., tantalum nitride, titanium nitride, tantalum carbide, titanium carbide, titanium aluminum carbide, tungsten silicide, tungsten nitride, ruthenium oxide, cobalt silicide, nickel silicide), carbon nanotube, conductive carbon, graphene, or any suitable combination of these materials. The conductive material can further include dopants that are incorporated during or after deposition.

Any known manner of depositing the metal contacts 84, 86 can be utilized. In some embodiments, the ILD 82 is patterned with open trenches and the metal contacts 84, 86 are deposited into the trenches. In some embodiments, the metal contacts 84, 86 are overfilled into the trenches to each form an overburden above a surface of the ILD 82. In some embodiments, a CMP selective to the ILD 82 removes the overburden.

Therefore, the exemplary embodiments of the present invention provide a method and structure for forming a Ge laser diode with direct bandgap for laser generation. The laser diode structure 85 includes thin Ge layers along <100> of less than 5 nm thickness (preferentially 3 nm or less) on oxide or nitride that serves as the intrinsic Ge active layers in the p-i-n laser diode. p+ and n+ regions can be formed with various semiconductors (Si, SiGe, or Ge) with different configurations of the laser diode structure. The laser diode structure 85 can potentially have efficient light emission at approximately 1550 nm from the direct band gap of Ge. Regarding FIG. 16, although not shown, the exemplary embodiment can further include mirrors, such as Bragg reflectors, below and above the lasing layers.

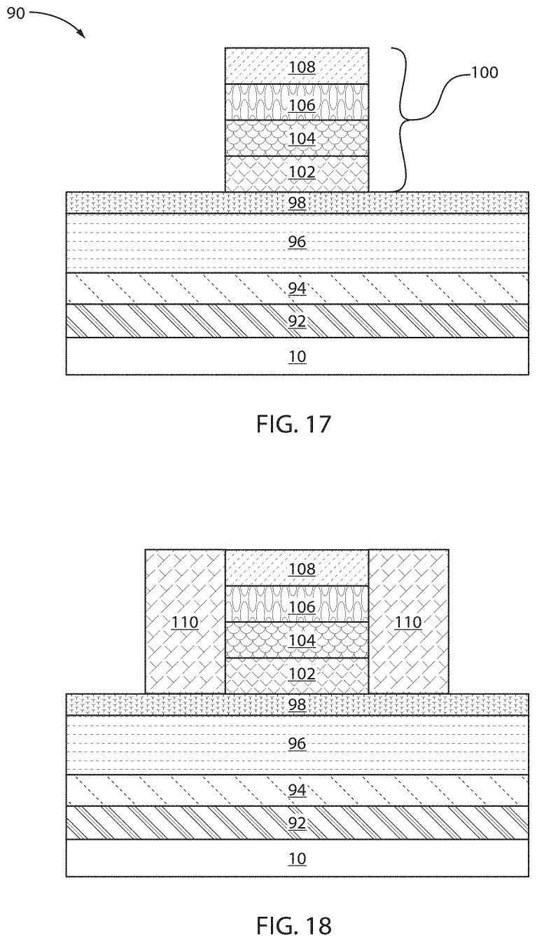

FIG. 17 is a cross-sectional view of a semiconductor structure where a stress film is deposited over a stack of semiconductor layers formed over a substrate, a portion of the stack patterned, in accordance with another embodiment of the present invention.

In another example embodiment, a graded SiGe strain relation buffer (SRB) layer 92 is formed over substrate 10. A sacrificial Si layer 94 is deposited over the graded SiGe SRB layer 92. A sacrificial SiGe layer 96 is deposited over the sacrificial Si layer 94. An n-type doped semiconductor layer 98 (or n+Si layer 98) is formed over the sacrificial SiGe layer 96. An n-type doped Ge layer 102 (n Ge layer 102) is formed over the n+Si layer 98. A p-type doped semiconductor layer 104 (p+ SiGe layer 104) is formed over the n Ge layer 102. A stress film 106 is formed over the p+ SiGe layer 104. A hardmask (HM) layer 108 is formed over the stress film 106. The stress film 106 can be, e.g., a stress nitride film.

In a non-limiting example, stress film thickness can range from about 30 nm to about 2000 nm (wide range), or from about 100 nm to about 500 nm (narrow range).

In a non-limiting example, for n-type doped Ge, the doping concentration can be about 5×10¹⁸/cm³ to about 3×10²¹ cm³ (wide range) or from about 1×10²⁰/cm³ to about 1×10²¹ cm³ (narrow range).

In a non-limiting example, the intrinsic layer (i-layer) can have a doping concentration that is less than about 2×10¹⁸/cm³ or less than about 5×10¹⁷/cm³.

The p+ SiGe layer 104, the n Ge layer 102, and the n+ Si layer 98 are collectively used to form a laser diode. The sacrificial SiGe layer 96 will be replaced with a stress film to produce tensile strain in the diode layers (98, 102, 104). The sacrificial Si layer 94 serves as an etch stop layer when the sacrificial SiGe layer 96 is etched. The stress film 106 will transfer tensile strain to the n Ge layer 102. For example, the HM layer 108 can have originally compressive stress. When HM layer 108 is patterned, it will attempt to stretch, and, thus, produce tensile strain to the underlying layers.

A stack of layers is patterned to create stack 100. Stack 100 includes n Ge layer 102, p+ SiGe layer 104, stress film 106, and HM layer 108. Structure 90 illustrates the stack 100 formed over the layers 92, 94, 96, 98. The stack 100 directly contacts the n+Si layer 98.

FIG. 18 is a cross-sectional view of the semiconductor structure of FIG. 17 where spacers are formed adjacent the patterned stack, in accordance with an embodiment of the present invention.

In various example embodiments, spacers 110 are formed adjacent the patterned stack 100. The spacers protect the stack 100 during a subsequent sacrificial SiGe etch process.

The spacers 110 can be composed of any one or more of SiN, SiBN, SiCN, SiOC, SiOCN and/or SiBCN films.

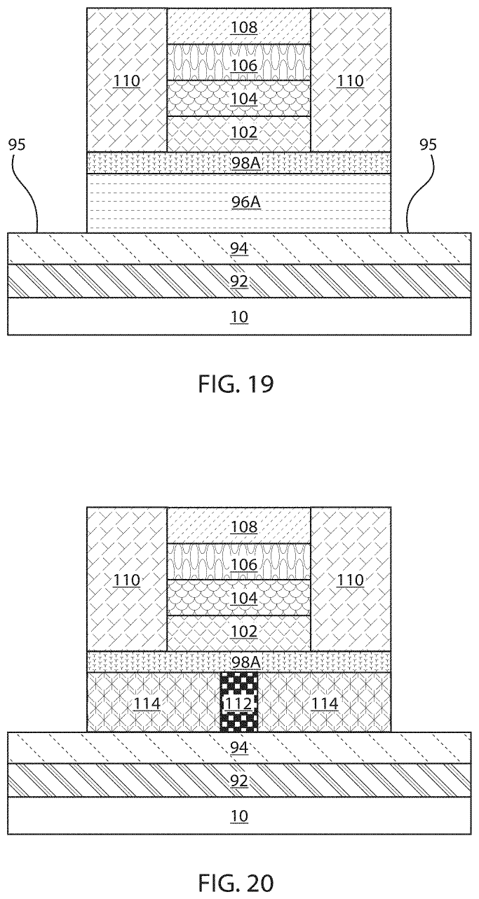

FIG. 19 is a cross-sectional view of the semiconductor structure of FIG. 18 where a directional etch takes place to expose a top surface of a sacrificial silicon (Si) layer, in accordance with an embodiment of the present invention.

In various example embodiments, a directional etch takes place to expose a top surface 95 of the sacrificial Si layer 94. The directional etch results in remaining sacrificial SiGe layer 96A and remaining n+Si layer 98A.

FIG. 20 is a cross-sectional view of the semiconductor structure of FIG. 19 where a sacrificial silicon germanium (SiGe) layer is undercut and a stress film is deposited in the undercut portion, in accordance with an embodiment of the present invention.

In various example embodiments, the remaining SiGe layer 96A is undercut selective to the remaining n+Si layer 98A, spacers 110, and HM layer 108. The sacrificial Si layer 94 under the remaining SiGe layer 96A protects the SiGe SRB layer 92 during the sacrificial SiGe etch process. A SiGe portion 112 remains directly between the sacrificial Si layer 94 and the remaining n+Si layer 98A.

The undercut regions adjacent the SiGe portion 112 are filled with a stress film 114. Stress film 114 can also be referred to as a stress nitride or stress nitride film. The undercut regions are filled with the stress film 114 by conformal deposition, planarization (e.g., CMP), and directional etch of the stress film (by, e.g., RIE).

In a non-limiting example, stress film thickness can range from about 30 nm to about 2000 nm (wide range), or from about 100 nm to about 500 nm (narrow range).

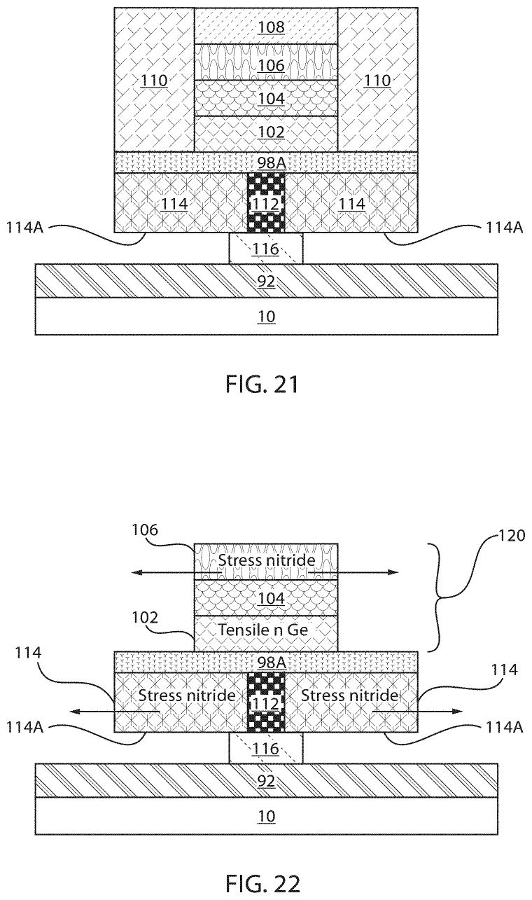

FIG. 21 is a cross-sectional view of the semiconductor structure of FIG. 20 where the sacrificial Si layer is selectively etched to create an undercut between the stress film and a graded SiGe strain relaxation buffer (SRB) layer, in accordance with an embodiment of the present invention.

In various example embodiments, the sacrificial Si layer 94 is selectively etched to create an undercut between the stress film 114 and the graded SiGe SRB layer 92. A Si portion 116 remains. The bottom surface 114A of the stress film 114 is exposed.

The sacrificial Si layer 94 is selectively etched by, e.g., ammonia etch, to create the undercut between the stress film 114 and the SiGe SRB layer 92.

FIG. 22 is a cross-sectional view of the semiconductor structure of FIG. 21 where the stress film is relaxed (or expanded) to produce tensile strain in the laser diode, in accordance with an embodiment of the present invention.

In various example embodiments, the spacers 110 and the HM layer 108 are removed. The compressive stress films 106, 114 attempt to relax (expand), thus producing tensile strain in the laser diode (p+ SiGe layer 104, n Ge layer 102, and remaining n+Si layer 98A). The tensile strain is produced in the n Ge layer 102 (designated as tensile n Ge). The stack 120 includes n Ge layer 102, p+ SiGe layer 104, and stress film 106. The arrows illustrate the relaxed or expanded state of the stress films 114, 106. The stress films 114, 106 can also be referred to as stress nitride films.

The advantage of this structure is that the diode is tensily strained by stress films 114, 106 at both the top and bottom of the diode, further enhancing the tensile strain in the diode. Moreover, the stress films 114, 106 can have a comparable thickness as the diode layers. Compressive nitride with 3-4 gigapascal (GPa) stress is commercially used in complementary metal oxide semiconductor (CMOS) technology. A back-of-envelop estimation results in approximately 2% tensile strain in the diode layers. This is almost one-order-of-magnitude higher than the strain level produced by the conventional thermal expansion method.

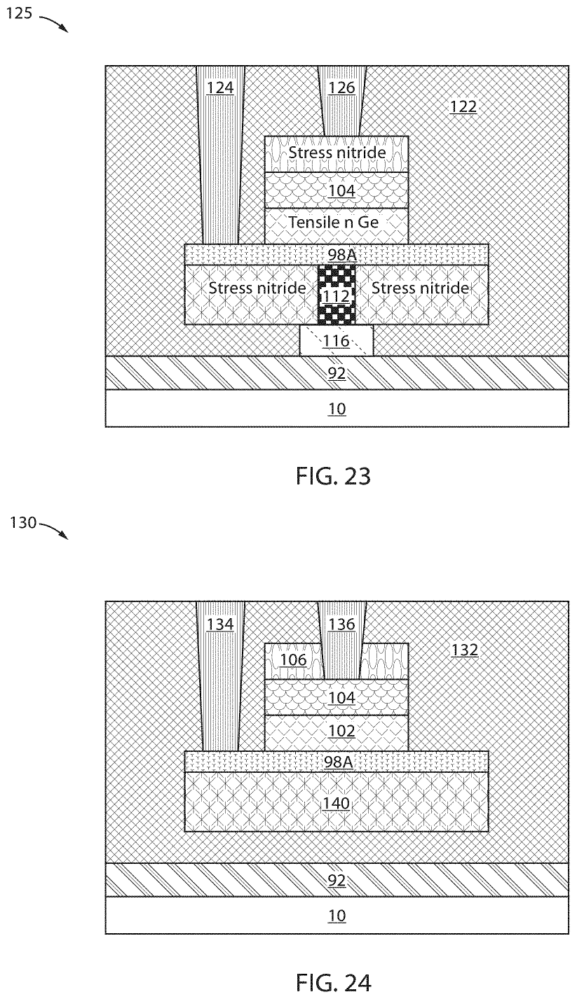

FIG. 23 is a cross-sectional view of the semiconductor structure of FIG. 22 where a further ILD is deposited and metal contacts are formed, in accordance with an embodiment of the present invention.

In various example embodiments, further ILD 122 is deposited and metal contacts 124, 126 are formed to the remaining n+Si layer 98A and stress film 106, respectively, to create laser diode structure 125.

Therefore, a tensily strained Ge laser is produced with stressors (e.g., stress films 106, 114) on top and underneath of the diode laser. In other words, the diode laser is confined directly between two stress films (106, 114). Stated differently, stress films 106, 114 directly contact top and bottom surfaces of the diode laser. p+ SiGe and n+Si (or SiGe) sandwich the n Ge layer to confine the lasing effect in the n Ge layer 102 (smaller bandgap than Si/SiGe).

FIG. 24 is a cross-sectional view of the semiconductor structure where a continuous layer of stress film is formed under the patterned stack of semiconductor layers, in accordance with another embodiment of the present invention.

In another embodiment, instead of relying on the sacrificial SiGe and the sacrificial Si pillars underneath the diode to anchor during fabrication, an external anchor can be provided at the ends of the stack. In this case, the entire sacrificial SiGe and Si can be removed and back-filled with stress film.

Structure 130 is based off of FIG. 19. However, as opposed to FIG. 19, structure 130 was formed by completely removing the remaining sacrificial Si layer 94. The stack 100 is then anchored to the substrate 10 by silicon oxycarbide (SiCO) anchors. A stress film 140 is formed in the undercut region between the SiGe SRB layer 92 and the remaining n+Si layer 98A. Then, an ILD 132 is deposited, and metal contacts 134, 136 are formed. As a result, the stress film 140 is underneath the entire diode. Stated differently, the entire top surface of the diode directly contacts the stress film 106 and the entire bottom surface of the diode directly contacts the stress film 140. Consequently, structure 130 is a Ge laser with enhanced tensile strain with buried stressor. A tensily strained Ge layer is formed on top of the Si substrate so that Ge can be used as a direct bandgap laser. Structure 130 can be referred to as a laser diode structure that can potentially have efficient light emission at approximately 1550 nm from the direct band gap of Ge.

Regarding FIGS. 23 and 24, although not shown, the exemplary embodiments can further include mirrors, such as Bragg reflectors, below and above the lasing layers.

In summary, the device structure of the exemplary embodiments of the present invention is a Ge laser structure including a single thin Ge layer along <100> of less than 5 nm thickness (preferentially 3 nm or less) on oxide or nitride that serves as the intrinsic Ge active layer in the laser diode. p+ and n+ region can be formed with various semiconductors (Si, SiGe, or Ge). The device structure of the exemplary embodiments of the present invention can be another Ge laser structure including a stack of alternating layers of thin Ge layers along <100> of less than 5 nm thickness (preferentially 3 nm or less) on oxide or nitride that serves as the intrinsic Ge active layer in the laser diode. The device structure of the exemplary embodiments of the present invention can be another Ge laser structure including epitaxially growing an SRB layer (e.g., graded SiGe) on top of a Si substrate, epitaxially growing a stack of sacrificial layers and Ge on the SRB layer, and forming stress films in both the top and bottom of the Ge laser layers to produce tensile strain in the Ge layer. The tensily strained Ge laser includes stressors (or stress films) on a top and bottom surface of the laser diode.

Therefore, the exemplary embodiments of the present invention include multiple embodiments related to constructing Ge-based lasers. The exemplary embodiments can be divided into two main categories of Ge-based lasers. One category of exemplary embodiments relates to Ge-based lasers employing ultra-thin Ge layers and the other category of exemplary embodiments relates to Ge-based lasers employing stress films to apply tensile strain in a Ge layer. These two approaches are additive. In other words, such approaches can be combined. Stated differently, one skilled in the art can contemplate a Ge-based laser constructed to include both ultra-thin Ge layers, as well as stress films to apply tensile strain to one or more Ge layers.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys. Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of a germanium (Ge) laser diode with direct bandgap for laser generation (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A method for forming a germanium (Ge) laser diode with direct bandgap for laser generation, the method comprising:
forming an intrinsic Ge active layer over a substrate;
forming a p+ region and an n+ region adjacent the intrinsic Ge active layer, wherein the p+ region, the n+ region, and the intrinsic Ge active layer collectively define a p-i-n diode; and
forming metal contacts to the p+ and n+ regions.

2. The method of claim 1, wherein the intrinsic Ge active layer has a thickness of 3 nm or less.

3. The method of claim 1, wherein the p+ and n+ regions are horizontally aligned with the intrinsic Ge active layer.

4. The method of claim 1, wherein the intrinsic Ge active layer is horizontally misaligned with respect to at least one of the p+ and n+ regions.

5. A method for forming a germanium (Ge) laser diode with direct bandgap for laser generation, the method comprising:
forming a stack including alternating intrinsic Ge active layers over a substrate;
forming a p+ region and an n+ region adjacent the stack including the alternating intrinsic Ge active layers, wherein the p+ region, the n+ region, and the alternating intrinsic Ge active layers collectively define a p-i-n diode; and
forming metal contacts to the p+ and n+ regions.

6. The method of claim 5, wherein each of the intrinsic Ge active layers has a thickness of 3 nm or less.

7. The method of claim 5, wherein the p+ and n+ regions directly contact sidewalls of the stack.

8. The method of claim 5, wherein dielectric layers separate the alternating intrinsic Ge active layers within the stack.

9. A method for forming a germanium (Ge) laser diode with enhanced tensile strain, the method comprising:
epitaxially growing a graded silicon germanium (SiGe) strain relaxation buffer (SRB) over a substrate;
epitaxially growing first and second sacrificial layers over the graded SiGe SRB;
forming an n-type doped semiconductor layer over the first and second sacrificial layers;
forming an n-type doped Ge layer over the n-type doped semiconductor layer;
forming a p-type doped semiconductor layer over the n-type doped Ge layer, wherein the n-type doped semiconductor layer, the n-type doped Ge layer, and the p-type doped semiconductor layer collectively define a diode; and
depositing a first stress film over the p-type doped semiconductor layer, wherein the first stress film subsequently transfers tensile strain to the n-type doped Ge layer.

10. The method of claim 9, wherein a stack including the first stress film, the p-type doped semiconductor layer, and the n-type doped Ge layer is patterned.

11. The method of claim 10, wherein, when the stress film is patterned, the stress film is stretched to produce tensile strain to the n-type doped Ge layer.

12. The method of claim 11, wherein spacers are formed on sidewalls of the stack.

13. The method of claim 12, wherein a directional etch is performed to etch the n-type doped semiconductor layer and the second sacrificial layer.

14. The method of claim 13, wherein the second sacrificial layer is undercut to expose a bottom surface of the n-type doped semiconductor layer in a first undercut region.

15. The method of claim 14, wherein a second stress film is deposited in the first undercut region.

16. The method of claim 15, wherein the first sacrificial layer is selectively etched to create a second undercut region.

17. The method of claim 16, wherein the spacers are removed.

18. The method of claim 17, wherein the first and second stress films are relaxed to transfer the tensile strain to the n-type doped Ge layer so that the diode becomes tensily strained.

19. The method of claim 18, wherein an inter-layer dielectric (ILD) is deposited.

20. The method of claim 19, wherein metal contacts are formed to the n-type doped semiconductor layer and the second stress film.

21. A germanium (Ge) laser diode with direct bandgap for laser generation, the Ge laser diode comprising:
a stack including alternating intrinsic Ge active layers disposed over a substrate;
a p+ region and an n+ region disposed adjacent the stack including the alternating intrinsic Ge active layers, wherein the p+ region, the n+ region, and the alternating intrinsic Ge active layers collectively define a p-i-n diode; and
metal contacts directly contacting the p+ and n+ regions.

22. The Ge laser diode of claim 21, wherein each of the intrinsic Ge active layers has a thickness of 3 nm or less.

23. The Ge laser diode of claim 21, wherein dielectric layers separate the alternating intrinsic Ge active layers within the stack.

24. A germanium (Ge) laser diode with enhanced tensile strain, the Ge laser diode comprising:
a stack disposed over a substrate, wherein the stack includes an n-type doped Ge layer, sandwiched by a p-type doped semiconductor layer and an n-type doped semiconductor layer, a first stress film and a second stress film abutting the p-type doped semiconductor layer and the n-type doped semiconductor layer, wherein the first stress film and the second stress film transfer tensile strain to the n-type doped Ge layer.

25. The Ge laser diode of claim 24, wherein the first and second stress films are relaxed to transfer the tensile strain to the n-type doped Ge layer so that the diode becomes tensily strained.
